(19) United States
(12) Patent Application Publication
(10) Pub. No.: US 2023/0283260 A1
(43) Pub. Date: Sep. 7, 2023

(54) NOTCH FILTER AND MULTI-FREQUENCY NOTCH FILTER

(71) Applicant: ANHUI ANUKI TECHNOLOGIES CO., LTD., Hefei, Anhui (CN)

(72) Inventors: Qilin SHI, Hefei, Anhui (CN); Chengjie ZUO, Hefei, Anhui (CN); Jun HE, Hefei, Anhui (CN)

(21) Appl. No.: 18/005,799

(22) PCT Filed: Apr. 9, 2021
(86) PCT No.: PCT/CN2021/086063

§ 371 Date: Jan. 17, 2023

(30) Foreign Application Priority Data
Mar. 17, 2021 (CN) 202110285755.0
Mar. 17, 2021 (CN) 202120555511.5

(51) Int. Cl. H03H 9/54; H03H 9/46; H03H 9/00

(52) U.S. Cl. CPC H03H 9/547; H03H 9/465; H03H 9/0095

(57) ABSTRACT

A notch filter and a multi-frequency notch filter. The notch filter includes at least one notch filtering unit, each of the at least one notch filtering unit includes an input port, an output port, at least three resonators and at least one inductive element, and the at least three resonators include at least two first resonators and at least one second resonator. The at least two first resonators are connected in series to each other, the at least two first resonators in series are connected in series between the input port and the output port, a first end of each of the at least one second resonator is connected to a connection point between two adjacent first resonators, and a second end of the each of the at least one second resonator is connected to a fixed potential end.

This application claims priority to Chinese Patent Application No. 202110285755.0 filed with the CNIPA on Mar. 17, 2021, the disclosure of which is incorporated herein by reference in its entirety.

### TECHNICAL FIELD

The present disclosure relates to the field of communication technologies, for example, to a notch filter and a multi-frequency notch filter.

### BACKGROUND

With the development of communication technology, the requirement for spectrum efficiency is getting higher and higher, and then a transmission frequency band spacing among different information is getting smaller and smaller in the process of information transmission. Therefore, a notch filter is required to have better notching characteristics to satisfy the requirements of information transmission.

Designers usually use lumped elements such as a capacitor and an inductor to form a notch filter or a microstrip circuit to form a notch filter, but the design dimension of the two filters is too large to meet the application requirements of small portable devices cannot be satisfied. In addition, the notch filter formed by the lumped elements such as a capacitor and an inductor or the notch filter formed by the microstrip circuit has lower quality factor and higher loss caused by notch.

### SUMMARY

The present disclosure provides a notch filter and a multi-frequency notch filter to solve the defect of large circuit dimension of the notch filter in the related art, so that the notch filter and the multi-frequency notch filter can satisfy the application requirements of small portable devices, improve notching characteristics and reduce notching loss.

A notch filter is provided and includes at least one notch filtering unit, each of the at least one notch filtering unit includes an input port, an output port, at least three resonators and at least one inductive element, and the at least three resonators include at least two first resonators and at least one second resonator. The at least two first resonators are connected in series to each other, the at least two first resonators in series are connected in series between the input port and the output port, a first end of each of the at least one second resonator is connected to a connection point between two adjacent ones of the at least two first resonators, a second end of the each of the at least one second resonator is connected to a fixed potential end, and each of the at least one inductive element is connected in parallel to one of the at least one second resonator.

A multi-frequency notch filter is provided and includes at least two notch filters, and the at least two notch filters are connected in series.

### BRIEF DESCRIPTION OF DRAWINGS

FIG. 1 is a structure diagram of a notch filter according to an embodiment of the present disclosure;

FIG. 2 is a performance diagram of a single resonator according to an embodiment of the present disclosure;

FIG. 3 is a performance diagram of three resonators connected to each other according to an embodiment of the present disclosure;

FIG. 4 is a performance diagram of a single notch filtering unit according to an embodiment of the present disclosure;

FIG. 5 is a performance diagram of a notch filtering unit resonator according to an embodiment of the present disclosure;

FIG. 6 is a structure diagram of another notch filter according to an embodiment of the present disclosure;

FIG. 7 is a performance diagram of different notch filters according to an embodiment of the present disclosure;

FIG. 8 is a structure diagram of a multi-frequency notch filter according to an embodiment of the present disclosure;

FIG. 9 is a structure diagram of another multi-frequency notch filter according to an embodiment of the present disclosure;

FIG. 10 is a performance diagram of the multi-frequency notch filter in FIG. 9 according to an embodiment of the present disclosure;

FIG. 11 is a structure diagram of another multi-frequency notch filter according to an embodiment of the present disclosure; and

FIG. 12 is a performance diagram of the multi-frequency notch filter in FIG. 11 according to an embodiment of the present disclosure.

### DETAILED DESCRIPTION

Technical solutions in embodiments of the present disclosure will be described in conjunction with drawings in the embodiments of the present disclosure.

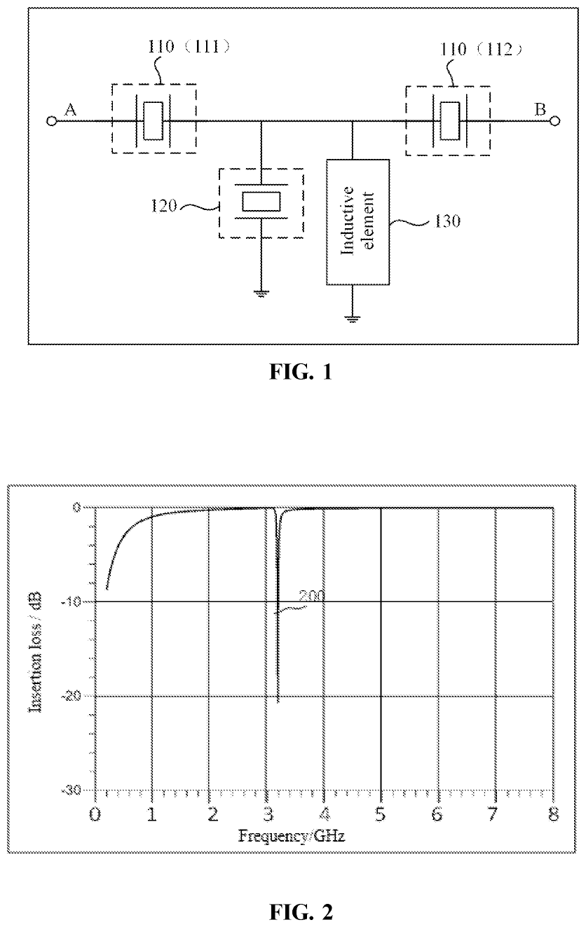

An embodiment of the application provides a structure diagram of a notch filter, and FIG. 1 is a structure diagram of a notch filter according to an embodiment of the present disclosure. As shown in FIG. 1, the notch filter includes at least one notch filtering unit, each of the at least one notch filtering unit includes an input port A, an output port B, at least three resonators and at least one inductive element 130, and the at least three resonators include at least two first resonators 110 and at least one second resonator 120. The at least two first resonators 110 are connected in series between the input port A and the output port B, a first end of each of the at least one second resonator 120 is connected to a connection point between two adjacent first resonators 110, a second end of the each of the at least one second resonator 120 is connected to a fixed potential end, and each of the at least one inductive element 130 is connected in parallel to one of the at least one second resonator 120.

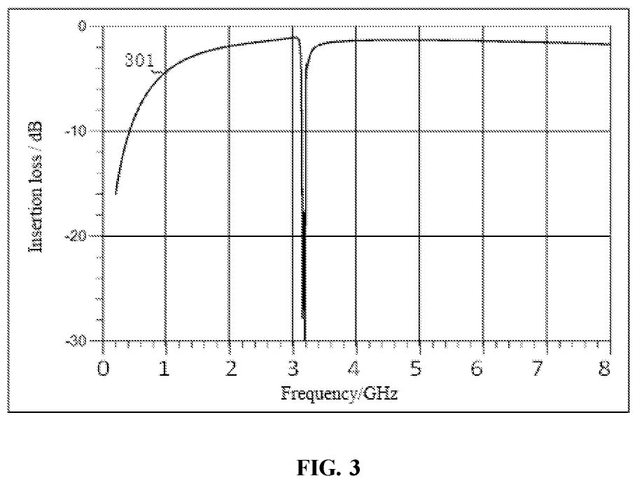

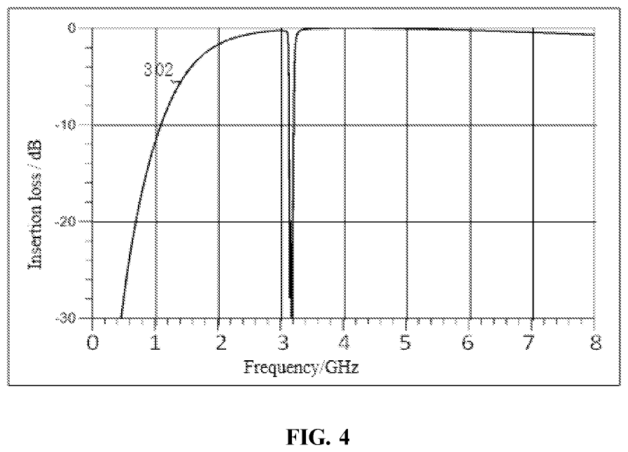

The notch filtering unit is a band elimination filter which can quickly attenuate an input signal in a frequency band to block the passage of a signal in the frequency band. A resonator can generate a resonant frequency, and the generated resonant frequency has characteristics of strong stability and strong anti-interference. The resonator is widely used in a variety of electronic products, and is configured to control the frequency. FIG. 2 is a performance diagram of a single resonator according to an embodiment of the present disclosure, where the abscissa represents a frequency of the resonator, and the ordinate represents an insertion loss of a signal. A curve 200 is a performance curve of a single resonator. As can be seen from FIG. 2, the single resonator has notching characteristics in its own response. In the present disclosure, the notch filtering unit is designed to include at least three resonators based on the notching characteristics of the resonator in its own response. The at least three resonators may be divided into two types: a first type is a first resonator 110 and a second type is a second resonator 120. The first resonator 110 includes at least two resonators with different resonant frequency characteristics connected in series between the input port A and the output port B, and an overlapping range of resonant frequencies of at least two first resonators 110 can be adjusted according to the requirement of a notching bandwidth, thereby improving a notching bandwidth of the notch filtering unit. The second resonator 120 includes at least one resonator with a resonant frequency characteristic different from that of the first resonator 110. A first end of the second resonator 120 is connected to a connection point between two adjacent first resonators 110, and a second end of the second resonator 120 is connected to a fixed potential end, in which way the second resonator 120 is connected between two adjacent first resonators 110, so that the suppression characteristics of the notch filtering unit can be improved. FIG. 3 is a performance diagram of three resonators connected to each other according to an embodiment of the present disclosure, where the abscissa represents a frequency of the resonators, and the ordinate represents an insertion loss of a signal. A curve 301 is a performance curve of three resonators connected to each other. Compared with FIG. 2 and FIG. 3, it can be seen that a notching bandwidth and a suppression effect of a single resonator are improved by using three resonators. The inductive element 130 is connected in parallel to the second resonator 120, which can adjust the loss value of the circuit to which at least three resonators are connected, i.e., adjusting the loss value of the circuit to which the first resonators 110 and the second resonator 120 are connected, so that the loss value of the notch filtering unit is reduced. FIG. 4 is a performance diagram of a single notch filtering unit according to an embodiment of the present disclosure, where the abscissa represents a frequency of the resonator, and the ordinate represents an insertion loss of a signal. A curve 302 is a performance curve of a single notch filtering unit. Comparing with FIG. 3 and FIG. 4, it can be seen that the loss value of the notch filtering unit is reduced after the inductive element 130 is connected in parallel to the second resonator 120. Therefore, in the present disclosure, based on the notch filtering unit formed by at least three resonators and at least one inductor, a suitable bandwidth and suppression characteristics can be designed according to the resonant frequencies of the resonators, a circuit dimension of the notch filter can be reduced, and the notching loss can be reduced.

Exemplarily, referring to FIG. 1, the notch filtering unit includes two first resonators 110, one second resonator 120 and one inductive element 130. A first end of a first one (i.e., a first resonator 111) of the two first resonators 110 is connected to an input port A, a second end of the first resonator 111 is connected to a first end of a second one (i.e., a first resonator 112) of the two first resonators 110, and a second end of the first resonator 112 is connected to an output port B. A first end of the second resonator 120 is connected to the second end of the first resonator 111, a second end of the second resonator 120 is connected to a fixed potential end, and the inductive element 130 is connected in parallel to the second resonator 120.

The two first resonators 110 included in the notch filtering unit are connected in series between the input port A and the output port B. The first end of the first resonator 111 is connected to the input port A which serves as an input port of the notch filtering unit, the second end of the first resonator 112 is connected to the output port B which serves as an output port of the notch filtering unit. The first end of the second resonator 120 included in the notch filtering unit is connected to the second end of the first resonator 111, and the second end of the second resonator 120 is connected to the fixed potential end. The two first resonators 110 included in the notch filtering unit includes have different resonant frequencies, and an overlapping range of the resonant frequencies of the two first resonators 110 can be adjusted according to the requirement of the notching bandwidth, so that the notching bandwidth of the notch filtering unit can be improved. The second resonator 120 included in the notch filtering unit is connected between the two first resonators 110, so that the suppression characteristics of the notch filtering unit can be improved. Therefore, the notch filter formed by a T-type circuit composed of three resonators makes full use of the resonant frequency characteristics of the resonators, and constitutes a notch filter with good notching characteristics, which can quickly attenuate the input signal in a frequency band to obstruct the passage of the signal in this frequency band. The inductive element 130 further included in the notch filtering unit can adjust the circuit. The inductive element 130 is connected in parallel to the second resonator 120 so that the loss value of the notch filtering unit is reduced and the notching characteristics of the notch filter are optimized.

Optionally, a difference between series resonant frequencies of the two first resonators is greater than 0 and is less than or equal to a notching bandwidth of the first one of the two first resonators.

Exemplarily, FIG. 5 is a performance diagram of a notch filtering unit resonator according to an embodiment of the present disclosure. The abscissa represents the frequency of the resonator, the ordinate represents the resistance value of the resonator, a curve 101 is a performance curve of the first resonator 111, and a curve 102 is a performance curve of the first resonator 112. An upper pole point P1 of a performance curve of each resonator represents a parallel resonant frequency of the each resonator, and a lower pole point P2 represents a series resonant frequency of the each resonator. As can be seen from FIG. 5, a series resonant frequency of the first resonator 111 is very close to a series resonant frequency of the first resonator 112, and a difference between the series resonant frequencies of the two first resonators 110 is greater than 0 and less than or equal to the notching bandwidth of the first resonator 111, thereby the series resonant frequencies of the two first resonators 110 partially overlap. When the two first resonators 110 are connected in series and the series resonant frequencies of the two first resonators 110 partially overlap, the series frequencies of the two first resonators 110 are merged together, so that the notching bandwidth of the notch filtering unit can be widened.

Optionally, a difference between the series resonant frequency of the second resonator and a parallel resonant frequency of the first one of the two first resonators is less than or equal to the notching bandwidth of the first one of the two first resonators.

Exemplarily, referring to FIG. 5, the curve 201 is a performance curve of the second resonator. As can be seen from FIG. 5, the series resonant frequency of the second resonator 120 is close to the parallel resonant frequency of the first resonator 111, and the series resonant frequency of the second resonator 120 is also close to the parallel resonant frequency of the first resonator 112 simultaneously, so that the difference between the series resonant frequency of the second resonator 120 and the parallel resonant frequency of the first resonator 111 is less than or equal to the notching bandwidth of the first resonator 111. Therefore, the series resonant frequency of the second resonator 120 is close to the parallel resonant frequencies of the two first resonators 110, and the second resonator 120 is connected between the two first resonators 110 so that the suppression effect of the notch filtering unit to the signal can be enhanced.

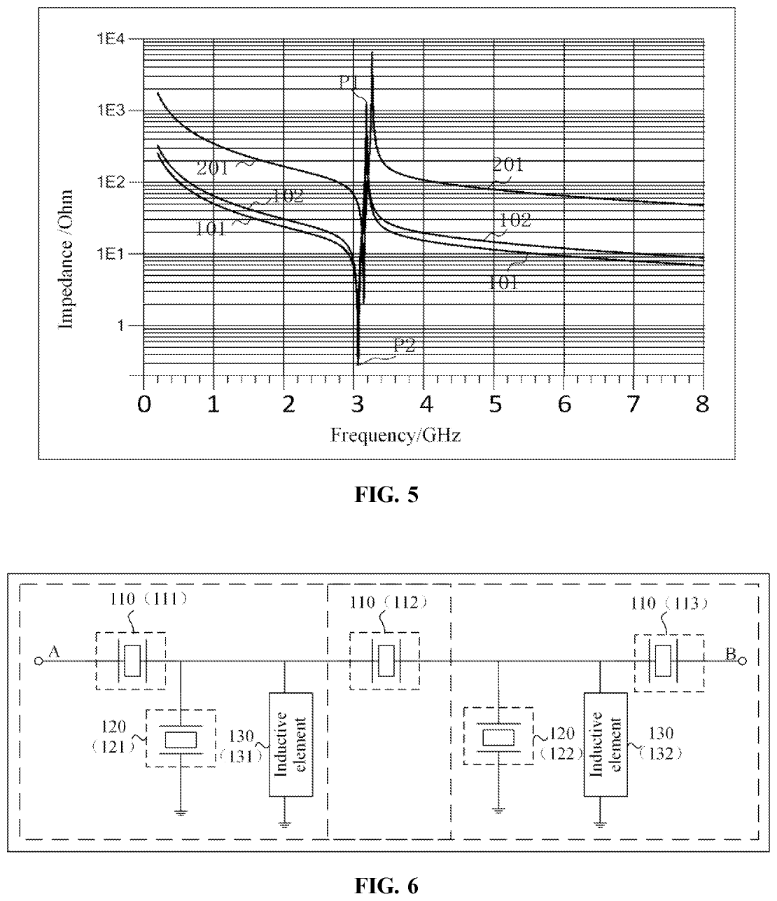

FIG. 6 is a structure diagram of another notch filter according to an embodiment of the present disclosure. As shown in FIG. 6, the notch filter includes at least two notch filtering units, and adjacent ones of the at least two notch filtering units share one first resonator 110.

Exemplarily, the notch filter includes two notch filtering units, and the two notch filtering units share one first resonator 110. The notch filter includes three first resonators 110, two second resonators 120 and two inductive elements 130. A first one of the three first resonators 110 (i.e., a first resonator 111), a second one of the three first resonators 110 (i.e., a second resonator 112) and a third one of the three first resonators 110 (i.e., a third resonator 113) are connected in series between an input port A and an output port B, a first end of the second resonator 121 is connected to a second end of the first resonator 111, and a second end of the second resonator 121 is grounded. A first end of the second resonator 122 is connected to a second end of the first resonator 112, a second end of the second resonator 122 is grounded, the inductive element 131 is connected in parallel to the second resonator 121, and the inductive element 132 is connected to the second resonator 122. An overlapping range of resonant frequencies of at least two notch filtering units can be adjusted according to the requirements of notching bandwidth, and the two notch filtering units are connected in series so that the resonant frequencies of the two notch filtering units are merged together, thereby improving the notching bandwidth of the notch filtering units. Therefore, the notch filter composed of two notch filtering units with close resonant frequencies makes full use of the notching characteristics of the resonators, and constitutes the notch filter with good notching characteristics, which can quickly attenuate the input signal in a frequency band to obstruct the passage of the signal in this frequency band, but causes relatively large loss of the input signal. In view of this defect, the circuit can be adjusted by the inductive element 131 and the inductive element 132 further included in the notch filtering unit, in which the inductive elements 130 are connected in parallel to the second resonators 120 so that the loss value of the notch filtering unit is reduced and the notching characteristics of the notch filter are optimized.

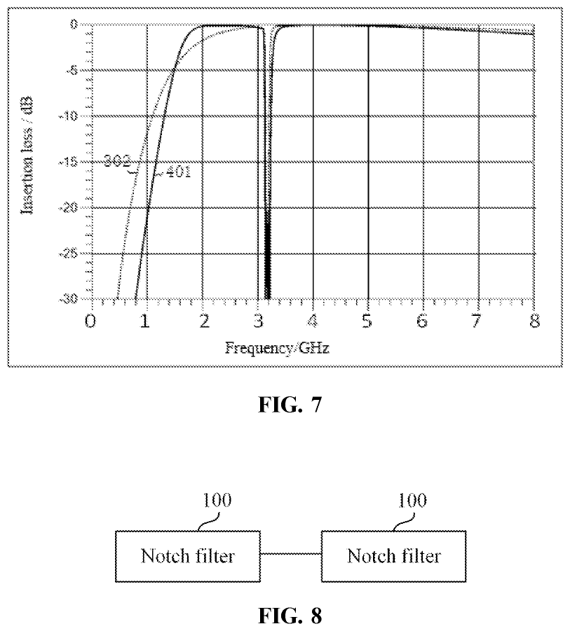

In addition, a notch filter composed of a plurality of notch filtering units has a larger notching bandwidth than a notch filter composed of a single filtering unit. FIG. 7 is a performance diagram of different notch filters according to an embodiment of the present disclosure. The abscissa represents a frequency of the notch filter, and the ordinate represents an insertion loss of the signal. A curve 302 is a performance curve of a notch filter composed of a single filtering unit, and a curve 401 is a performance curve of a notch filter composed of two filtering units. As can be seen from FIG. 7, the notch filter composed of two filtering units has a larger filter bandwidth range than the notch filter composed of the single filtering unit.

The notching bandwidth range of the notch filter is set according to the notching bandwidth required by the input signal. In other embodiments, the notch filter may adjust the notching bandwidth by adjusting the number of notch filtering units.

Optionally, a sum of equivalent impedance of the one inductive element and an equivalent impedance of the two first resonators and the one second resonator is less than the equivalent impedance of the two first resonators and the one second resonator.

The circuit can be adjusted by the inductive element. The inductive element is connected in parallel to the second resonator, so that the equivalent impedance of the first resonators and the second resonator can be adjusted by the equivalent impedance of the inductive element, thus reducing the overall impedance value of the notch filtering unit. According to Ohm's law, the parallel circuit has the characteristic that the resistance value becomes smaller when more elements connected in parallel. Since the inductive element is connected in parallel to the second resonator, the inductive element is configured to reduce the overall resistance value of the circuit. It can be seen that the sum of the equivalent impedance of the one inductive element and the equivalent impedance of the two first resonators and the one second resonator is less than the equivalent impedance of the two first resonators and the one second resonator. The loss value of the connection circuit of the first resonators and the second resonator is adjusted by reducing an equivalent resistance value of the overall circuit, so that the loss value of the notch filtering unit is reduced.

Exemplarily, referring to FIGS. 3 and 4, the loss characteristic of the curve 301 is larger than that of the curve 302, and the overall characteristic curve of the notch filtering unit without an inductive element is shifted downwardly relative to that of the notch filtering unit with an inductive element, that is, the loss increases. Therefore, the impedance of the notch filter circuit can be adjusted by the inductive element to reduce the overall impedance value of the notch filtering unit, thereby reducing the loss value of the notch filtering unit.

Optionally, the inductive element includes an inductance element, and the inductance element is connected in parallel to the second resonator.

The notch filter is composed of chip inductor elements manufactured based on Low Temperature Co-fired Ceramic (LTCC) and surface mount device (SMD) technology, which can reduce the dimension of notch filter and satisfy the requirements of handheld mobile application devices. The inductive element is connected in parallel to the second resonator, which can adjust the impedance of the notch filter circuit to reduce the overall impedance value of the notch filtering unit, thereby reducing the loss value of the notch filtering unit.

Optionally, the resonator includes at least one of a surface acoustic wave resonator, a bulk acoustic wave resonator, or a film bulk acoustic resonator.

By utilizing the piezoelectric properties of piezoelectric materials, the surface acoustic wave (SAW) resonator mainly uses an input and output transducer to convert the input signal of a radio wave into mechanical energy with an input and output transducer, and then converts the mechanical energy processed into an electrical signal, so as to achieve that unnecessary signals and noises are filtered out to improve the quality of reception. The SAW resonator is simpler to install and smaller in volume than a conventional inductor-capacitor (LC) filter. An acoustic wave in the bulk acoustic wave resonator propagates vertically. Very high quality can be achieved by storing the acoustic wave energy in the piezoelectric materials, so that the bulk acoustic wave resonator can be converted into a highly competitive device with large out-of-band attenuation. The film bulk acoustic resonator (FBAR) has characteristics of high Q value and easy miniaturization. The SAW resonator, the bulk acoustic wave resonator and the FBAR all have the characteristics of small volume, low cost and high Q factor, and can satisfy the filtering requirements of highly specific and high performance. The SAW resonator is suitable for lower frequencies (up to 2.7 GHz), while bulk acoustic wave resonator and the FBAR are suitable for higher frequencies (2.7 GHz to 6 GHz).

FIG. 8 is a structure diagram of a multi-frequency notch filter according to an embodiment of the present disclosure. As shown in FIG. 8, the multi-frequency notch filter includes at least two notch filters 100 provided in the above embodiments, and the at least two notch filters 100 are connected in series.

The multi-frequency notch filter includes the notch filters provided in any embodiments of the present disclosure and therefore has the effect of the notch filters provided in the embodiments of the present disclosure, which will not be repeated here.

Optionally, the number of notch filtering units in a different notch filter is the same or different.

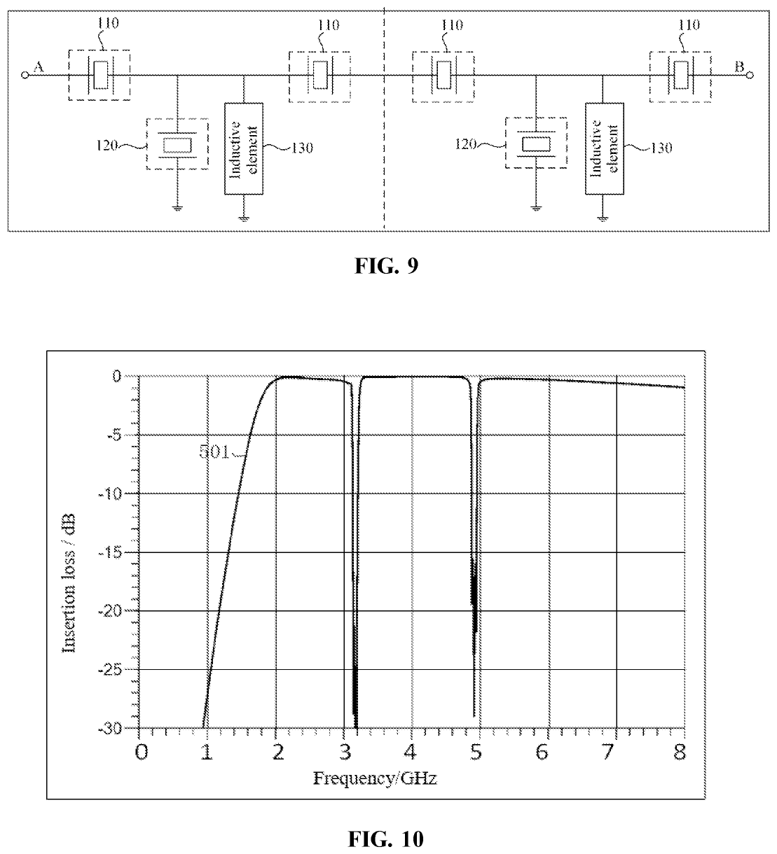

Exemplarily, FIG. 9 is a structure diagram of another multi-frequency notch filter according to an embodiment of the present disclosure. As shown in FIG. 9, the multi-frequency notch filter is composed of two notch filters connected in series, each notch filter including a single notch filtering unit. Six resonators of the multi-frequency notch filter have different resonant frequencies. FIG. 10 is a performance diagram of the multi-frequency notch filter in FIG. 9 according to an embodiment of the present disclosure. The abscissa represents a frequency of the multi-frequency notch filter, and the ordinate represents an insertion loss of the signal. A curve 501 is a performance curve of the multi-frequency notch filter in FIG. 9. As can be seen from FIG. 10, the notching frequencies of the multi-frequency notch filter are about 3.2 and 4.9.

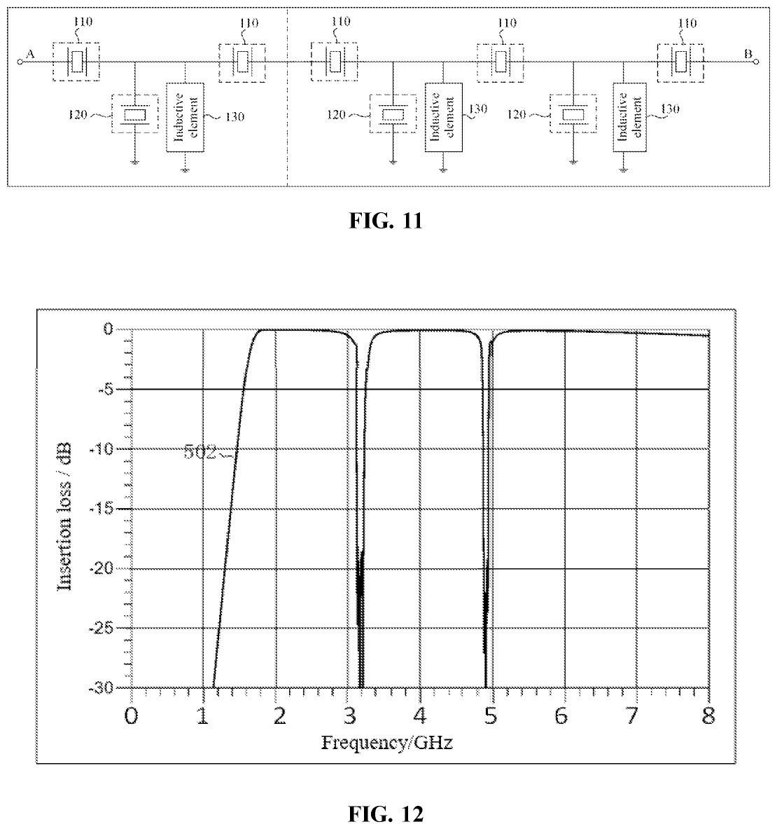

Exemplarily, FIG. 11 is a structure diagram of another multi-frequency notch filter according to an embodiment of the present disclosure. The multi-frequency notch filter is composed of two notch filters connected in series, one of which includes a single notch filtering unit and the other one of which includes two notch filtering units. Eight resonators of the multi-frequency notch filter have different resonant frequencies. FIG. 12 is a performance diagram of the multi-frequency notch filter in FIG. 11 according to an embodiment of the present disclosure. The abscissa represents a frequency of the multi-frequency notch filter, and the ordinate represents an insertion loss of the signal. A curve 502 is a performance curve of the multi-frequency notch filter in FIG. 11. As can be seen from FIG. 12, the notching frequencies of the multi-frequency notch filter are about 3.2 and 4.9.

1. A notch filter, comprising at least one notch filtering unit, wherein each of the at least one notch filtering unit comprises an input port, an output port, at least three resonators and at least one inductive element, and the at least three resonators comprise at least two first resonators and at least one second resonator;
wherein the at least two first resonators are connected in series to each other, the at least two first resonators in series are connected in series between the input port and the output port, a first end of each of the at least one second resonator is connected to a connection point between two adjacent ones of the at least two first resonators, a second end of the each of the at least one second resonator is connected to a fixed potential end, and each of the at least one inductive element is connected in parallel to one of the at least one second resonator.

2. The notch filter of claim 1, wherein each of the at least one notch filtering unit comprises two first resonators, one second resonator and one inductive element; and
wherein a first end of a first one of the two first resonators is connected to the input port, a second end of the first one of the two first resonators is connected to a first end of a second one of the two first resonators, and a second end of the second one of the two first resonators is connected to the output port; a first end of the one second resonator is connected to the second end of the first one of the two first resonators, a second end of the one second resonator is connected to the fixed potential end, and the one inductive element is connected in parallel to the one second resonator.

3. The notch filter of claim 2, wherein a difference between series resonant frequencies of the two first resonators is greater than 0 and is less than or equal to a notching bandwidth of the first one of the two first resonators.

4. The notch filter of claim 3, wherein a difference between a series resonant frequency of the one second resonator and a parallel resonant frequency of the first one of the two first resonators is less than or equal to the notching bandwidth of the first of the two first resonators.

5. The notch filter of claim 2, wherein the notch filter comprises at least two notch filtering units; and adjacent ones of the at least two notch filtering units share one first resonator.

6. The notch filter of claim 2, wherein a sum of an equivalent impedance of the one inductive element and an equivalent impedance of the two first resonators and the one second resonator is less than the equivalent impedance of the two first resonators and the one second resonator.

7. The notch filter of claim 6, wherein the one inductive element comprises an inductance element.

8. The notch filter of claim 6, wherein the two first resonators and the one second resonator comprise at least one of a surface acoustic wave resonator, a bulk acoustic wave resonator, or a film bulk acoustic resonator.

9. A multi-frequency notch filter, comprising at least two notch filters of claim 1, and the at least two notch filters are connected in series.

10. The multi-frequency notch filter of claim 9, wherein a number of notch filtering units in a different notch filter is the same or different.

11. A multi-frequency notch filter, comprising at least two notch filters of claim 2, and the at least two notch filters are connected in series.

12. A multi-frequency notch filter, comprising at least two notch filters of claim 3, and the at least two notch filters are connected in series.

13. A multi-frequency notch filter, comprising at least two notch filters of claim 4, and the at least two notch filters are connected in series.

14. A multi-frequency notch filter, comprising at least two notch filters of claim 5, and the at least two notch filters are connected in series.

15. A multi-frequency notch filter, comprising at least two notch filters of claim 6, and the at least two notch filters are connected in series.

16. A multi-frequency notch filter, comprising at least two notch filters of claim 7, and the at least two notch filters are connected in series.

17. A multi-frequency notch filter, comprising at least two notch filters of claim 8, and the at least two notch filters are connected in series.
